(19) United States
(12) Patent Application Publication
(10) Pub. No.: US 2026/0211045 A1
(43) Pub. Date: Jul. 23, 2026

(54) BATTERY MANAGEMENT SYSTEMS AND METHODS

(71) Applicant: Moment Energy Inc., Coquitlam (CA)

(72) Inventors: Grayson Reid HALLIDAY, Coquitlam (CA); Gabriel Giles SOARES, Coquitlam (CA)

(73) Assignee: Moment Energy Inc., Coquitlam, BC (CA)

(21) Appl. No.: 19/143,225

(22) PCT Filed: Jan. 19, 2024
(86) PCT No.: PCT/IB2024/050542

§ 371 Date: Jun. 25, 2025

Related U.S. Application Data
(60) Provisional application No. 63/440,181, filed on Jan. 20, 2023.

(51) Int. Cl. G01R 31/367; G01R 31/388; G01R 31/392; H01M 10/44; H01M 10/46; H01M 10/48; H02J 7/82; H02J 7/90

(52) U.S. Cl. CPC G01R 31/367; G01R 31/388; G01R 31/392; H01M 10/441; H01M 10/443; H01M 10/46; H01M 10/482; H01M 10/486; H02J 7/82; H02J 7/933

(57) ABSTRACT

Systems and methods described herein can determine battery characteristics (e.g., SOC or SOH) using ML models trained with measurements from random walk battery testing. A processor can generate, according to a first constraint, a first random value for a first current to charge a battery and a second random value, according to a second constraint different than the first constraint, for a second current to discharge the battery. The processor can measure a first voltage corresponding to the first current and a second voltage corresponding to the second current. The processor can determine, based on the first current, the first voltage, the second current and the second voltage input into ML model trained using randomly generated currents and measurements for charging and discharging a plurality of batteries, a state of charge (SOC) of the battery. The processor can operate the battery according to the SOC.

### CROSS-REFERENCE TO RELATED PATENT APPLICATIONS

This application claims the benefit of and priority to U.S. Provisional Application 63/440,181, filed Jan. 20, 2023, incorporated herein by reference in its entirety.

### BACKGROUND

Batteries can have a variety of applications and can be used to provide power to various objects or devices, which can have varying demands on the batteries themselves.

### SUMMARY

Machine learning (ML) models to determine state of charge (SOC) of batteries with diverse conditions or characteristics can be unreliable for testing of extended life or second life batteries. For instance, use of static test cycles for ML based battery assessments can constrain the test coverage, leading to ML datasets covering only a limited spectrum of battery condition permutations and combinations. This can result in performance issues and introduce errors in the ML models trained on such datasets, diminishing their accuracy and reliability in predicting performance characteristics of such batteries, such as SOC or state of health (SOH). For example, data collection techniques based on a constant-current, constant-voltage (CCCV) approach can lack coverage of current variations, hysteresis effects from current polarity transitions as well as time-dependent battery effects resulting from current magnitude transitions across the SOC profile. Likewise, federal urban driving schedule (FUDS) based testing can include a limited number of current variations and a profile biased toward discharge rather than charge currents, leading to sparse charge data. Similarly, dynamic stress test (DST) based tests can face challenges with limited current variations and profiles favoring discharge currents and resulting in a lack of charge data. Uniform application of such test profiles for tested batteries can lead to ML model performance challenges, including data overfitting that can cause the ML model to capture noise or random fluctuations in the data that are not representative of the underlying data pattern. This can, in turn, cause the ML model to make inference errors when predicting battery characteristics (e.g., SOCs or SOHs), thereby falling short of accurate and reliable performance for long-life and second-life battery testing.

The technical solutions of this disclosure overcome these challenges using ML models to determine battery characteristics, such as battery SOC or SOH, that were trained with voltage, temperature, and current measurements derived from random walk testing that can apply random charge and discharge currents to batteries across a broad range of battery conditions. By randomizing the charge and discharge currents applied to the batteries to produce voltage or other measurements for use with the ML model, the technical solutions can expand the dataset profile over an entire range of battery conditions and characteristics, diversifying the dataset and reducing the chance of the ML model performance issues, such as data overfitting. The data collection process can include random walk patterns including a combination of sequences of random currents with alternating polarities in various arrangements covering at least a portion of tested battery's profile across the SOC range. In doing so, the technical solutions improve the encoding of the battery characteristics or conditions, including factors such as varying SOC, SOH, current, hysteresis, and time-dependent processes like lithium diffusion within the collected dataset. By gathering such random walk data across a diverse range of batteries, the technical solutions provide an ML model that accurately and reliably predicts SOCs throughout the battery lifespan, rendering it suitable for long life and second life battery assessment applications.

At least one aspect of the technical solutions is directed to a system. The system can include one or more processors coupled with memory to generate, according to a first constraint, a first random value for a first current to charge a battery for a first time duration. The one or more processors can generate, according to a second constraint different than the first constraint, a second random value for a second current to discharge the battery for a second time duration. The one or more processors can measure a first voltage corresponding to the first current and a second voltage corresponding to the second current. The one or more processors determine, based at least on the first current, the first voltage, the second current and the second voltage input into a machine learning (ML) model trained using at least a plurality of randomly selected currents to charge a plurality of batteries and a plurality of randomly selected currents to discharge the plurality of batteries, a state of charge (SOC) of the battery. The one or more processors can operate the battery according to the SOC.

The one or more processors can identify a dataset comprising a plurality of SOCs for a plurality of batteries. For example, each SOC of the plurality of SOCs can correspond to one or more timestamped measurements of at least one of a voltage, a temperature or a current of a battery of the plurality of batteries. For example, each of the plurality of timestamped measurements can be measured using at least the plurality of randomly selected currents. The one or more processors can train the ML model using the dataset.

The one or more processors can select the first random value for the first current from a first range of currents between the first constraint and a third constraint. The first constraint can correspond to a first magnitude that is greater than a third magnitude of the third constraint. The one or more processors can select the second random value for the second current from a second range of currents between the second constraint and a fourth constraint. The second constraint can correspond to a second magnitude that is greater than a fourth magnitude of the fourth constraint and the fourth magnitude can be greater than at least one of the first magnitude or the third magnitude.

The one or more processors can identify a temperature at which the first voltage and the second voltage are measured. The one or more processors can determine, based at least on the temperature input into the ML model, the SOC of the battery. The one or more processors can identify a starting SOC of the battery, a target SOC of the battery, a capacity of the battery, a coulombic efficiency of the battery and a target temperature for testing the battery. The one or more processors can generate the first random value for the first current and the second random value for the second current according to the starting SOC, the target SOC, the capacity, the coulombic efficiency and the target temperature.

The battery can include a plurality of battery cells and the starting SOC can correspond to a starting average SOC of the plurality of battery cells. The target SOC can correspond to a target average SOC of the plurality of battery cells. The capacity can correspond to an average capacity of the plurality of battery cells. The coulombic efficiency can correspond to an average coulombic efficiency of the plurality of battery cells. The target temperature can correspond to an average temperature of the plurality of battery cells.

The one or more processors can identify, based on a rule for derating current, that the first random value for the first current exceeds a threshold for a maximum current rating for the battery. The one or more processors can derate the first current according to the maximum current rating. The one or more processors can generate, according to the first constraint, a first plurality of random values for a first plurality of currents to charge the battery. The first plurality of random values can include the first random value for the first current. The one or more processors can generate, according to the second constraint, a second plurality of random values of currents to discharge the battery. The second plurality of random values can include the second random value for the second current. The one or more processors can measure a first plurality of voltages corresponding to the first plurality of currents and a second plurality of voltages corresponding to the second plurality of currents. The one or more processors can determine the SOC of the battery based at least on the first plurality of currents, the first plurality of voltages, the second plurality of currents and the second plurality of voltages input into the ML model.

The one or more processors can determine charging and discharging cycles for the battery based at least on the SOC. The one or more processors can determine a state of health (SOH) of the battery using the charging and discharging cycles.

At least one aspect of the technical solutions is directed to a method. The method can include one or more processors coupled with memory generating, according to a first constraint, a first random value for a first current to charge a battery for a first time duration. The method can include generating, by the one or more processors, according to a second constraint different than the first constraint, a second random value for a second current to discharge the battery for a second time duration. The method can include the one or more processors measuring a first voltage corresponding to the first current and a second voltage corresponding to the second current. The method can include the one or more processors determining a state of charge (SOC) of the battery. The method can determine the SOC based at least on the first current, the first voltage, the second current and the second voltage input into a machine learning (ML) model trained using at least a plurality of randomly selected currents to charge a plurality of batteries and a plurality of randomly selected currents to discharge the plurality of batteries. The method can include operating, by the one or more processors, the battery according to the SOC.

The method can include the one or more processors identifying a dataset comprising a plurality of SOCs for a plurality of batteries. Each SOC of the plurality of SOCs can correspond to one or more timestamped measurements of at least one of a voltage, a temperature or a current of a battery of the plurality of batteries. Each of the plurality of timestamped measurements can be measured using at least the plurality of randomly selected currents. The method can include training, by the one or more processors, the ML model using the dataset.

The method can include selecting, by the one or more processors, the first random value for the first current is selected from a first range of currents between the first constraint and a third constraint. The first constraint can correspond to a first magnitude that is greater than a third magnitude of the first constraint. The method can include the one or more processors selecting the second random value for the second current from a second range of currents between the second constraint and a fourth constraint. The second constraint can correspond to a second magnitude that is greater than a fourth magnitude of the fourth constraint and the fourth magnitude can be greater than at least one of the first magnitude or the third magnitude.

The method can include the one or more processors identifying a temperature at which the first voltage and the second voltage are measured. The method can include the one or more processors determining, based at least on the temperature input into the ML model, the SOC of the battery.

The method can include the one or more processors identifying a starting SOC of the battery, a target SOC of the battery, a capacity of the battery, a coulombic efficiency of the battery and a target temperature for testing the battery. The method can include the one or more processors generating, the first random value for the first current and the second random value for the second current according to the starting SOC, the target SOC, the capacity, the coulombic efficiency and the target temperature.

The battery can include a plurality of battery cells. The battery can include the starting SOC corresponding to a starting average SOC of the plurality of battery cells, the target SOC corresponding to a target average SOC of the plurality of battery cells, the capacity corresponding to an average capacity of the plurality of battery cells, the coulombic efficiency corresponding to an average coulombic efficiency of the plurality of battery cells and the target temperature corresponding to an average temperature of the plurality of battery cells.

The method can include the one or more processors identifying, based on a rule for derating current, that the first random value for the first current exceeds a threshold for a maximum current rating for the battery. The method can include derating, by the one or more processors, the first current according to the maximum current rating.

The method can include the one or more processors generating, according to the first constraint, a first plurality of random values for a first plurality of currents to charge the battery. The first plurality of random values can include the first random value for the first current. The method can include the one or more processors generating, according to the second constraint, a second plurality of random values of currents to discharge the battery. The second plurality of random values can include the second random value for the second current. The method can include the one or more processors measuring a first plurality of voltages corresponding to the first plurality of currents and a second plurality of voltages corresponding to the second plurality of currents. The method can include the one or more processors determining the SOC of the battery based at least on the first plurality of currents, the first plurality of voltages, the second plurality of currents and the second plurality of voltages input into the ML model.

At least one aspect of the technical solutions is directed to a non-transitory computer readable media having processor readable instructions. The instructions can be such that, when executed, cause at least one processor to generate, according to a first constraint, a first random value for a first current to charge a battery for a first time duration. The instructions can be such that, when executed, cause at least one processor to generate, according to a second constraint different than the first constraint, a second random value for a second current to discharge the battery for a second time duration. The instructions can be such that, when executed, cause at least one processor to measure a first voltage corresponding to the first current and a second voltage corresponding to the second current. The instructions can be such that, when executed, cause at least one processor to determine one of a state of charge (SOC) of the battery or a state of health (SOH) of the battery. The one SOC or the SOH can be determined based at least on the first current, the first voltage, the second current and the second voltage input into a machine learning (ML) model trained using at least a plurality of randomly selected currents to charge a plurality of batteries and a plurality of randomly selected currents to discharge the plurality of batteries. The instructions can be such that, when executed, cause at least one processor to operate the battery according to the SOC or the SOH.

These and other aspects and implementations are discussed in detail below. The foregoing information and the following detailed description include illustrative examples of various aspects and implementations and provide an overview or framework for understanding the nature and character of the claimed aspects and implementations. The drawings provide illustration and a further understanding of the various aspects and implementations and are incorporated in and constitute a part of this specification. The foregoing information and the following detailed description and drawings include illustrative examples and should not be considered as limiting.

### BRIEF DESCRIPTION OF THE DRAWINGS

The accompanying drawings are not intended to be drawn to scale. Like reference numbers and designations in the various drawings indicate like elements. For purposes of clarity, not every component may be labeled in every drawing. In the drawings:

FIG. 1 illustrates an example system to determine battery characteristics using ML models trained with a dataset generated using random walk battery testing.

FIG. 2 illustrates a block diagram of an example computing or a computer system.

FIG. 3 illustrates an example of battery cells of an energy storage system having various characteristics and conditions exhibited during charge and discharge cycles.

FIG. 4 illustrates an example of a battery management system (BMS) for managing battery packs of an energy storage system.

FIG. 5 illustrates an example of a system having a chain of modular, scalable analog front-end boards performing cell voltage, temperature and balancing control measurements for battery cells.

FIG. 6 illustrates an example of SOC labels corresponding to measurements collected during testing.

FIG. 7 illustrates an example graph of a comparison of a plot of measured SOC values and a plot of ML model 112 outputs 114 (e.g., SOC determinations).

FIG. 8 illustrates a method for determining battery characteristics using ML models trained with datasets generated with measurements gathered via random walk battery testing.

### DETAILED DESCRIPTION

A battery management system (BMS) can be used for extended life battery applications, such as second life batteries. Second life batteries can include batteries applied to a different use after the initial use or lifecycle is completed, such as batteries from electric vehicles being repurposed to provide energy storage for buildings. Batteries can have diverse conditions and characteristics, which can make accurate and reliable assessments of their performance characteristics challenging.

Following below are more detailed descriptions of various concepts related to, and implementations of ML models for determining battery characteristics (e.g., SOC or SOH) using random walk testing measurements based on random charge and discharge currents applied to batteries under test. The various concepts introduced above and discussed in greater detail below may be implemented in any of numerous ways. This disclosure generally relates to systems and methods for testing batteries, including without limitation, ML-based determination of state of charge (SOC) of batteries using data generated from random currents.

ML based SOC or SOH testing or determination can suffer from performance challenges rendering these methodologies too inaccurate and unreliable for extended life or second-life battery applications. These processes normally use data collection via constant-current, constant-voltage (CCCV) cycling, dynamic stress test (DST), or benchmark drive cycles such as the federal urban driving schedule (FUDS). Static test cycles for ML dataset generation result in testing coverage that is limited with respect to the full set of battery condition permutations and combinations. For instance, CCCV cycling testing datasets lack current variations throughout the SOC profile, hysteresis effects as a result of current polarity transitions, and time-dependent battery effects as a result of current magnitude transitions throughout the SOC profile. FUDS based tests can suffer from limited or discrete number of current variations throughout the SOC profile and a profile that favors discharge direction in which charge data is sparse. DTS can similarly suffer from limited number of current variations throughout the SOC profile and can have a profile that favors discharge direction, making charge data sparse. Additionally, by subjecting each battery to the same test profile, the generated ML model increases the likelihood of overfitting data to the specific test behavior, result in increased performance inaccuracy and errors, making such unreliable.

The solutions in this disclosure overcome these challenges using an ML model trained to determine battery SOC based on voltage, temperature, and current measurements obtained from random walk testing. The random walk testing can utilize user provided input parameters, such as starting and target SOCs, battery capacity and coulombic efficiency and target temperature to implement random charge and discharge currents to test the batteries accounting for a varied range of conditions. Using this approach, the technical solutions generate a more diverse and randomized dataset, reducing the risk of data overfitting, drifting and other ML performance issues, leading to more accurate and reliable SOC determinations for various battery conditions. The data collection process can include sequences of random charge and discharge currents, with a random walk process covering the entire SOC profile by alternately charging and discharging the battery, accounting for various aspects of battery performance, including variations in SOC, SOH, current, hysteresis, and time-dependent processes, such as lithium diffusion. By collecting data across various battery modules and a variety of different conditions, the technical solutions provide a ML model efficiently and reliably predicting battery SOC over the entire battery lifespan.

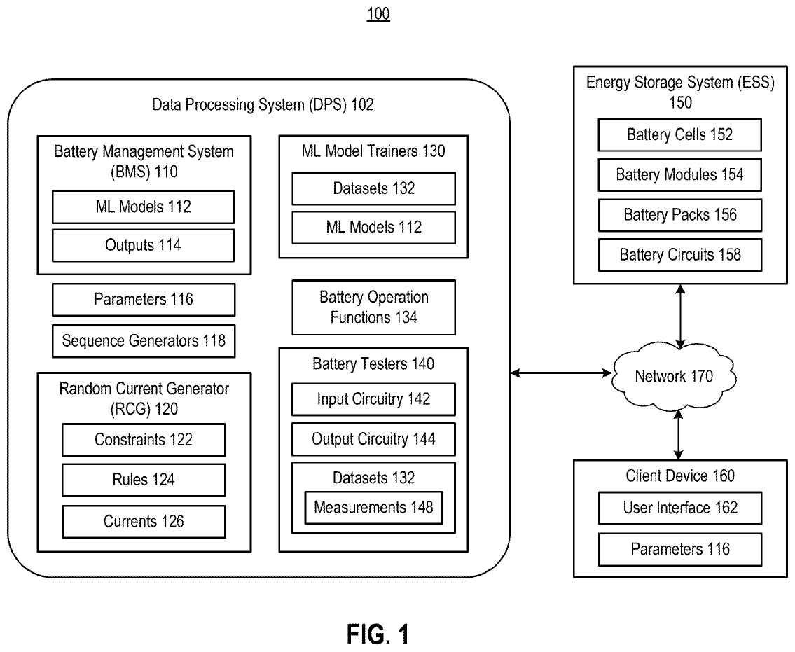

FIG. 1 illustrates an example system 100 to determine battery characteristics (e.g., SOC or SOH) using ML models trained with a dataset generated using random walk battery testing. System 100 can include one or more centralized or distributed data processing systems (DPSs) 102 communicating, via one or more networks 170, with one or more client devices 160 and energy storage systems (ESSs) 150. Client device 160 can include one or more user interfaces 162 for a user (e.g., a battery test technician) to provide parameters 116 for the DPS 102 to test batteries at the ESS 150. ESS 150 can include battery circuits 158 as well as battery cells 152, battery modules 154 (e.g., having a group of battery cells 152) and battery packs 156 (e.g., having a group of battery modules 154 with battery cells 152). DPS 102 can include one or more battery management systems (BMSs) 110, parameters 116, sequence generators 118, random current generators (RCGs) 120, ML model trainers 130, battery operation functions 134 and battery testers 140. BMS 110 can include one or more ML models 112 that can use measurements 148 from the battery testers 140 as input to generate modeled outputs 114, such as predicted values of battery characteristics, including battery SOC or SOH. ML model trainer 130 can include datasets 132 to train ML models 112. RCGs 120 can utilize rules 124 and constraints 122 to generate or determine or generate random charge or discharge currents 126. Sequence generators 118 can use the random currents 126 to provide a sequence of random walk tests (e.g., sequences of current charges and discharges) to test a battery (e.g., cell 152, module 154 or pack 156). Battery testers 140 include input circuitry 142 (e.g., current and voltage sources or temperature controlling devices) and output circuitry 144 (e.g., current or voltage monitors, coulomb counter and temperature sensors) to generate measurements 148 for the datasets 132, based on the parameters 116 provided from the client device 160. The measurements 148 generated using outputs (e.g., voltage or current measurements) from the currents 126 can be input into the ML model 112 to provide outputs 114 including SOC or SOH determinations. DPS 102 can include battery operation functions 134 to operate the batteries of the ESS 150 based on the determined characteristics (e.g., SOC or SOH).

DPS 102 can include any combination of hardware and software to determine battery characteristics (e.g., SOC or SOH) using machine learning. DPS 102 can be implemented centrally on a single device (e.g., a server, a computer or a virtual machine) or can be dispersed or distributed across a plurality of devices or platforms, such as any combination of multiple computing devices, virtual machines or cloud computing. DPS 102 can include the functionality to utilize or trigger an RCG 120 to generate charging and discharging currents 126 with random magnitudes or random time durations in accordance with constraints 122 or rules 124. DPS 102 can include or utilize a sequence generator 118 to create sequences of the randomly generated charging and discharging currents 126 to facilitate a random walk functionality in which charging and discharging currents 126 can be implemented in a particular direction (e.g., towards an increased SOC or decreased SOC). Sequence generator 118 or random RGC 120 can utilize parameters 116 from a client device 160 to determine constraints 122 (e.g., a range within which random value of for the magnitude of current is to be selected or generated). DPS 102 can include the functionality to trigger or use battery testers 140 to generate measurements 148 which can be used as inputs into ML model 112 to generate outputs 114 (e.g., SOCs, SOHs or other characteristics of the elements of the ESS 150 being tested (e.g., battery cells 152, modules 154 or packs 156). Datasets 132 from various measurements 148 of multiple batteries (e.g., 152, 154 or 156) can be used by the ML model trainer 130 to train or retrain ML models 112 for accurate and reliable battery characteristic determinations (e.g., predictions of SOC or SOH).

ESS 150 can include any number of battery cells 152, battery modules 154 having any number of battery cells and battery packs 156 having any number of battery modules 154 or battery cells 152 in any arrangement, such as any combination of parallel and series connectivity or arrangement. Batteries (e.g., collectively cells 152, modules 154 or packs 156) can include us types of batteries, including rechargeable batteries that can be utilized in extended life or second-life applications. Batteries can be suitable for testing for characteristics determinations, such as SOC or SOH, using ML models 112. Battery cells 152 can be grouped or arranged into modules 154 or packs 156 of any voltage and current output. Battery cells 152 can include, for example, lithium-ion cells, nickel-metal hydride cells, and lead-acid cells. Battery modules 154, which can include interconnected battery cells 152, can include configurations like prismatic modules, pouch modules, and cylindrical modules. Battery packs 156, which can include multiple battery modules 154 or multiple arrangement of battery cells 152, can include diverse formats such as those found in electric vehicles (EVs), consumer electronics, and stationary energy storage systems.

Battery management system (BMS) 110 can include any combination of hardware and software for managing energy storage system 150, including any one or more battery cells 152, battery modules 154 or battery packs 156). BMS 110 can be equipped with one or more ML models 112 designed to utilize measurements 148 obtained from battery testers 140, such as voltage or temperatures, to determine SOC or SOH of batteries (e.g., cells 152, modules 154 or packs 156). BMS 110 can include or utilize battery operation function 134 to operate any one or more batteries (e.g., 152, 154 or 156) based on the determined outputs 114 (e.g., determinations of SOC or SOH), using for example battery operation functions 134 to operate the battery according to the determined outputs 114. BMS 110 can utilize an ML model 112 to processes measurements 148 used as inputs into the ML model 112 to generate outputs 114. Battery management system 110 can include or be coupled with one or more battery testers 140 for testing batteries.

Client device 160 can include any computing device or a system for a user to input values of parameters 116. Client device 160 can include a computer, a laptop or a cloud computing system providing an application with a user interface 162 to provide parameters 116. Parameters 116 can include any input values for any combination of: a starting SOC value (e.g., between 0% and 100% of SOC), a target SOC value, a capacity of the battery (e.g., capacity of battery cell 152, module 154 or pack 156), a battery coulombic efficiency and a target or a desired temperature. These parameters 116 can be used as inputs to the sequence generator 118 to establish a charging set of constraints 122 within which random charging currents 126 (e.g., randomly selected magnitudes of charging currents 126) are to be generated or selected. These parameters 116 can be used as inputs to the sequence generator 118 to establish a discharging set of constraints 122 within which random discharging currents 126 (e.g., randomly selected magnitudes of discharging currents 126) are to be generated. Random current generator 120 can use the constraints 122 defining the ranges between which the charging currents 126 and the discharging currents 126 can be generated to generate, select or determine the random values corresponding to the magnitude of the charge and discharge currents 126. The currents 126 can be adjusted or corrected to conform to the rules 124, such as the rules to maintain the charge or discharge within particular battery capacity limits or to not exceed a particular temperature.

Network 170 can include any communication network connecting the DPS 102, ESS 150 and client devices 160, to facilitate exchange of data and control commands between the two entities. Network 170 can include the Internet as a communication medium, enables seamless interaction for monitoring, managing, and retrieving information related to energy storage operations. Through standardized communication protocols, network 170 can be used for transmission of real-time data, between DPS 102, client devices 160 or ESSs 150.

Battery testers 140 can include any combination of hardware and software to test a battery of an ESS 150 (e.g., any battery cell 152, battery module 154 or battery pack 156). Battery testers 140 can include the functionality to implement the sequences of charging and discharging currents 126 as a random walk sequence. The random walk sequence can include, for example, a sequence of charging and discharging currents which that are overall configured to increase the SOC of a battery from a low SOC (e.g., 20% SOC) to a high SOC (e.g., 95% SOC). The random walk sequence can include, for example, a combination of three random magnitude charging currents of charging values that combine for a higher coulomb charge than a single discharging current of the random magnitude. This configuration of the random walk test can test the battery that uses a combination of charging and discharging currents 126 to test a battery from a lower SOC to a higher SOC.

Conversely, a random walk sequence can include discharging currents that in combination provide a greater overall coulomb charge discharged from a tested battery than the amount of coulomb charge input into the battery by one or more charging currents. As such a random walk sequence in the direction of discharging a battery can include several discharge currents interrupted by one or more charging currents, where all of the currents have random values, but the constraints 122 for the discharge currents are biased to have a greater value of discharge coulombs of charge from the battery than a value of coulombs of charge provided to the battery. To generate the measurements 148, the battery tester 140 can use the charging and discharging currents sequenced according to a random walk technique generated by the sequence generator 118 (e.g., a random walk biased for charging of the battery or a random walk biased for discharging of the battery) and measure the measurements 148 as voltage, power, coulomb or temperature measurements captured by the output circuitry 144. Measurements 148 can then be input into the ML model 112 to produce the outputs 114 (e.g., SOC or SOH) of the battery.

In an example, a user operating the client device seeks to assess the performance of a lithium-ion battery module. Through the user interface 162 at a client device 160, a user can input parameters 116 for testing a battery from an ESS 150 (e.g., one or more cells 152, modules 154 or packs 156). For instance, parameters 116 can specify a starting SOC of 20%, a target SOC of 80%, a battery capacity of 2000 mAh, a coulombic efficiency of 95%, and a target test temperature of 25° C. These parameters can then be processed by the random current generator 120, which can generate or configure constraints 122 to achieve the specified change in SOC (e.g., from 20% to 80%). Sequence generator 118 can utilize RCG 120 to utilize constraints 122 and rules 124 to generate a sequence of random charge and discharge currents 126. The sequence can include three charging currents 126 having randomly selected amperage magnitudes between 1.5 A and 4 A, where the three charging currents 126 are interrupted or alternated by two discharging currents 126 having a randomly selected amperage between 1.0 A and 1.5 A. The currents 126 can be set to a same or a different time duration, such as 1 minute, 2 minutes, 5 minutes, 10 minutes or 15 minutes. In some examples, the time duration is randomly selected from a value between a range of constraints 122 for a given time period.

The sequence of currents can then be applied to the battery (e.g., 152, 154 or 156) being tested and measurements 148 (e.g., voltage, power, temperature or current) can be captured by the output circuitry 144 (e.g., volt meters, current meters or power meters) of the battery tester 140. Measurements 148 can then be input into a ML model 112, which can be trained by the ML model trainer 130 on diverse datasets including random walk testing scenarios of a plurality of batteries (e.g., cells 152, modules 154 or packs 156), to analyze the input data and generate outputs 114. Outputs 114 can include determinations of battery characteristics such as SOC and SOH.

Measurements 148 can include any measurements of battery characteristics, such as measurements of voltage, current, power or temperature. Measurements 148 can be taken using output circuitry 144 of battery testers 140. Output circuitry 144 can include any device for taking measurements 148, such as volt or power meters, current meters or temperature sensors or gauges. For instance, measurements 148 can include voltage or current readings that can be gathered during a random walk implementation of one or more sequences of charge and discharge currents 126 having randomly selected magnitudes.

Constraints 122 can define a range for the random values indicative of the magnitude of each of the charge or discharge currents 126. Constraints 122 can be configured or established to provide a range within which a magnitude of a charging or discharging current 126 is to be selected. Constraints 122 can cover larger or smaller values, depending on the desired direction of the random walk sequence, such as towards an increased SOC or towards a decreased SOC. For instance, when parameters 116 indicate that a starting SOC is smaller than target SOC, the charging current constraints 122 can be set by the sequence generator 118 or RCG 120 to be larger than that of the constraints 122 for the discharge currents. In doing so, the configured constraints 122 can bias the randomly selected charging currents 126 to overall exceed the discharging currents 126 whose magnitude can be randomly selected from a set of constraints defining a smaller range of currents. For instance, when parameters 116 indicate that a starting SOC is larger than target SOC, the discharging current constraints 122 can be set to be larger than that of the constraints 122 for the charging currents 126, so as to facilitate random discharging currents 126 to be overall larger than the random charging currents 126.

Datasets 132 can include any number of measurements 148 from any number of batteries (e.g., battery cells 152, battery modules 154 or battery packs 156). Datasets 132 can include voltage, current, power, temperature, coulomb measurements or any other data or information for describing operation of a battery. Datasets 132, as well as measurements 148, can be stored in a database in a storage (e.g., storage 225). Datasets 132 can include measurements 148 taken from any number of batteries of the same type (e.g., same make and model) or diverse makes and models. Datasets 132 can be selective based on the battery configuration. For example, dataset 132 can include measurements 148 of battery cells 152. For example, a dataset 132 can include measurements 148 of battery modules 154 having a plurality of battery cells (e.g., 24, 36, 48, or 100 battery cells) within a single package (e.g., a module). For example, a dataset 132 can include measurements 148 within a battery pack 156 having a plurality of battery modules 154, or plurality of battery cells 152 (e.g., in a configuration where battery packs 156 include only cells 152 and no modules 154).

Battery circuits 158 can include any combination of hardware and software for managing operation of the ESS 150. Battery circuits 158 can facilitate operation and usage of battery cells 152, packs 156, and modules 154 within an Energy Storage System (ESS) 150. Battery circuits 158 can include, for instance, one or more analog or digital circuits or control boards implementing temperature measurement, maintaining thermal control and stability, measuring and monitoring electrical potential across individual cells 152, modules 154 or packs and balancing energy to equalize charge among cells to prevent capacity discrepancies.

ML model 112 can include any machine learning model for determining a characteristic or operation of a battery (e.g., cells 152, module 154 or pack 156). ML models 112 can be configured or trained to generate outputs 114 that can include any determinations of battery characteristics, such as a state of charge (SOC), state of health (SOH), remaining useful life of a battery, charging and discharging patterns or trends, fault detection, temperature profile, cycle count, degradation rate, charge capacity or efficiency of the battery. ML model 112 can provide outputs 114 utilizing measurements 148 input into the model. ML model 112 can be configured or trained to determine outputs 114 based on a training on a dataset 132 of a large number of measurements 148 of a large number of batteries. As dataset 132 is developed using measurements 148 gathered via random walk methodology, ML model 112 can make reliable determinations (e.g., outputs 114) across various battery conditions and configurations.

ML model 112 can be implemented using various features and technologies. ML models 112 can utilize any type of machine learning modeling, including deep learning techniques, such as neural networks. For instance, ML model 112 can utilize convolutional, graph or recurrent neural networks, long short-term memory (LSTM) for handling temporal aspects or transformers for attention mechanisms and weighted features for improved detection of dependencies in the data. Feature engineering can include extraction of relevant information from measurements. Examples of features include voltage readings corresponding to random charge and discharge currents, temperature data, and the duration of specific current applications. ML model 112 can be based on regression algorithms for predicting continuous values like SOC or classification algorithms for categorical predictions like SOH categories. ML model 112 can utilize time-series analysis to address the temporal nature of battery behavior over a plurality of charge and discharge currents 126.

ML model trainer 130 can include any combination of hardware and software for training an ML model 112. ML model trainer 130 can include the functionality to leverage datasets 132 having measurements obtained from various random walk currents 126 applied to tested batteries (e.g., 152, 154 or 156). These datasets 132 can encompass diverse operational scenarios, capturing voltage, temperature, and current outputs during randomized charge and discharge cycles, allowing the ML model trainer 130 to train the ML model 112 for a variety of battery conditions. ML model trainer 130 can facilitate training of the ML model 112 using any technique, such as supervised learning, feature engineering, data augmentation, cross-validation, hyperparameter tuning, ensemble learning, recurrent neural networks (RNNs), or long short-term memory (LSTM) networks or using any other technique or feature. The training process can include exposing the ML model 112 to a multitude of battery conditions, allowing the model to discern patterns, correlations, and dependencies within the data. Through iterative adjustments of model parameters or weights, the ML model trainer 130 can refine the model's ability to accurately predict outputs 114 (e.g., SOC, SOH, battery capacity, useful life or other relevant battery characteristics).

Battery operation functions 134 can include any combination of hardware and software for performing battery operation or management. Battery operation functions 134 can include functions for the BMS 110 to control or manage battery operation using the outputs 114 (e.g., SOC or SOH of the battery). Battery operation functions 134 can include energy management functions, such as operations to control the charging and discharging cycles of the battery. Battery operation functions 134 can include battery charge and discharge control, such as control the level up to which battery is to be charged or discharged. Battery operation functions 134 can include battery health monitoring, such as cycle counting. Battery operation functions 134 can include functions for managing load to the battery or preventing overcharging or undercharging of the battery.

In an example, system 100 can include DPS 102 executing a random walk script that implements a series of charge and discharge currents 126 for generating measurements 148. In an example, a detailing a sequence of 15 timesteps with specific configurations can be implemented. The sequence can indicate a date at which it is run, along with a temperature. The script can indicate a runtime duration in hours and minutes. The script can be configured with a starting SOC of 1%, a target end SOC of 99%, a battery capacity of 100 Ah, coulombic efficiency of 100%, 3 major cycle steps, 1 minor cycle step, and a timestep of 2 minutes. The table below presents the elapsed time in seconds, corresponding current values in Amperes, and the associated SOC percentages at each timestep. The sequence demonstrates the dynamic interplay of charge and discharge currents, reflecting the random nature of the RW testing approach in assessing battery performance across diverse SOC profiles.

RW Sequence Generation: Date
RW Sequence Temperature: 25 C.
RW Sequence Execution Runtime: Duration in Hours

| Time(s) | Current(A) | SOC(%) |
|---|---|---|
| 0 | 6.73A | 1.00% |
| 120 | 49.317 | 1.22% |
| 240 | 70.992 | 2.87% |
| 360 | −13.257 | 5.23% |
| 480 | 27.956 | 4.79% |
| 600 | 37.833 | 5.72% |
| 720 | 7.216 | 6.99% |
| 840 | −16.275 | 7.23% |
| 960 | 18.479 | 6.68% |
| 1080 | 37.888 | 7.30% |
| 1200 | 48.372 | 8.56% |
| 1320 | −35.636 | 10.18% |
| 1440 | 44.638 | 8.99% |
| 1560 | 11.489 | 10.48% |
| 1680 | 9.323 | 10.86% |

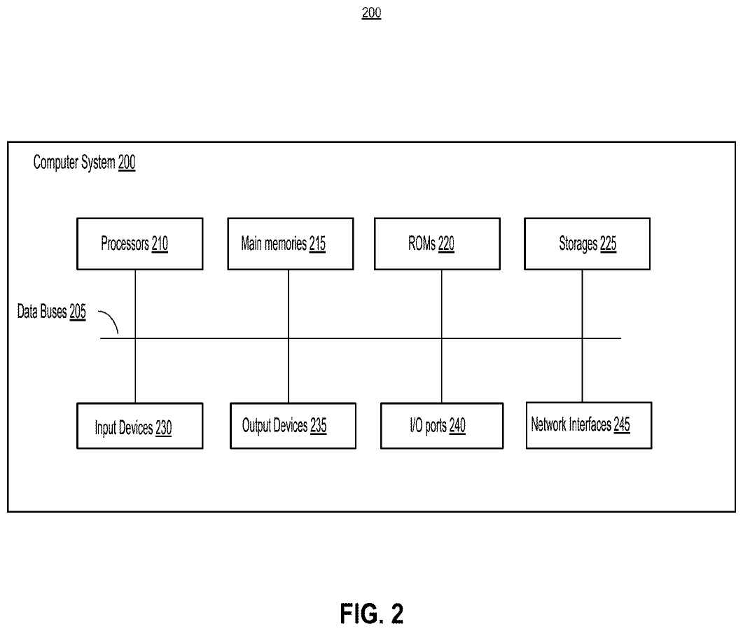

FIG. 2 illustrates a block diagram of an example computing or a computer system 200. Computer system or a computing system 200 can include various components for processing or computing digital data. Computer system 200 can be used as a platform or a system on which any function, feature or implementation of example system 100 can be implemented, using for instance, instructions, commands, computer code or data stored and executed in one or more processors. For instance, computer system 200 can be included in and execute any device or function, such as a DPS 102 or client device 160. Computer system 200 can be used for operating, implementing or running DPS 102 elements, such as BMS 110, ML model 112, battery operations functions 134, battery tester 140, sequence generator 118 or random current generator.

Computer system 200 can include at least one bus data bus 205 or other communication component or feature for communicating information and at least one processor 210 or processing circuit coupled to the data bus 205 for processing such information or data. Computer system 200 can include one or more processors 210 or processing circuits coupled to the data bus 205 for exchanging or processing data or information. Computing system 200 can include one or more main memories 215, such as a random access memory (RAM), dynamic RAM (DRAM) or other dynamic storage device, which can be coupled to the data bus 205 for storing information and instructions to be executed by the processor(s) 210. Main memory 215 can be used for storing information (e.g., data, computer code, commands or instructions) during execution of instructions by the processor(s) 210.

Computing system 200 can include one or more read only memories (ROMs) 220 or other static storage device coupled to the bus 205 for storing static information, data, code and instructions for the processor(s) 210. Storage 225 can include any storage device, such as a solid state device, magnetic disk or optical disk, which can be coupled to the data bus 205 to persistently store information and instructions.

Computing system 200 can be coupled via the data bus 205 to one or more output devices 235, such as speakers or displays, such as organic light emitting displays (OLEDs), liquid crystal displays or active matrix displays, that can be used for displaying or providing information to a user. Input devices 230, such as keyboards, touch screens or voice interfaces, can be coupled to the data bus 205 for communicating information and commands to the processor(s) 210. Input device 230 can include, for example, a touch screen display (e.g., output device 235). Input device 230 can include a cursor control, such as a mouse, a trackball, or cursor direction keys, for communicating direction information and command selections to the processor(s) 210 for controlling cursor movement on a display.

Computer system 200 can include input/output ports 240, also referred to as I/O ports 240, that can include physical interfaces that facilitate or provide communication between external or peripheral devices and processor(s) 210 and/or memory 215. I/O ports 240 can be connected to data bus 205, allowing the transfer of data between the processor(s) 210, memories 215, and any external devices (e.g., keyboards, mice, printers, and external storage devices). Computer system 200 can also include one or more network interfaces 245 coupled via data buses 205 to facilitate network communication. Network interfaces 245 can include any physical or virtual components enabling communication between the computer system 200 and any external networks (e.g., the Internet). Network interface 245 can provide transfer of data between the processor(s) 210, memories 215 and any external networks.

The technical solutions, such as systems and methods described herein, can be implemented by the computing system 200 in response to the processor 210 executing an arrangement of instructions contained in main memory 215. Such instructions can be read into main memory 215 from another computer-readable medium, such as the storage device 225. Execution of the arrangement of instructions contained in main memory 215 causes the computing system 200 to perform the illustrative processes described herein. One or more processors 210 in a multi-processing arrangement may also be employed to execute the instructions contained in main memory 215. Hard-wired circuitry can be used in place of or in combination with software instructions together with the systems and methods described herein. Systems and methods described herein are not limited to any specific combination of hardware circuitry and software.

Although an example computing system has been described in FIG. 2, the subject matter including the operations described in this specification can be implemented in other types of digital electronic circuitry, or in computer software, firmware, or hardware, including in virtual machines or environments, on the cloud-based systems or structures disclosed in this specification and their structural equivalents, or in combinations of one or more of them.

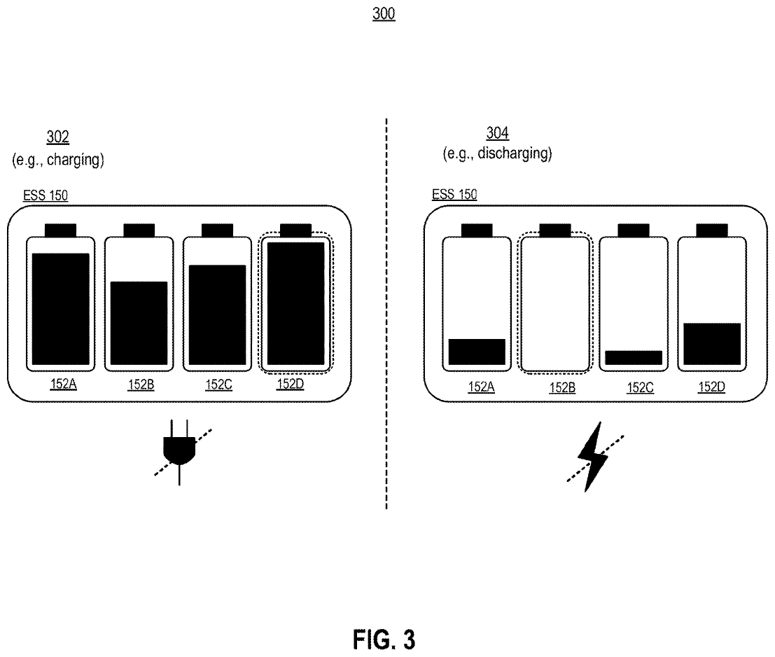

FIG. 3 illustrates an example 300 of battery cells 152 of an energy storage system 150 with various characteristics and conditions exhibited during charge and discharge cycles. As illustrated in example 300, an ESS 150 can have its overall capacity limited by the weakest cell 152 in the system given that charging or discharging halts after a single cell reaches either 100% SOC during a charge cycle or 0% SOC during a discharge cycle. This can result in inefficiencies during both the charge and discharge processes as available capacity cannot be utilized.

In views 302 and 304 of example 300, ESS 150 can have four battery cells 152A, 152B, 152C and 152D having different performance characteristics or conditions. As shown in view 302 of example 300, during a charge cycle, battery cell 152D can be the first cell in the ESS 150 to reach the 100% SOC and be fully charged. As a result, other battery cells 152, such as cell 152B may be insufficiently charged. As shown in view 304 of example 300, during a discharge cycle, battery cell 152B can be the first cell in the ESS 150 to reach the 0% SOC and be fully discharged. As a result, other battery cells 152, such as cell 152D, can may be insufficiently discharged and still store some energy. These variations in battery cell conditions and performance can cause inefficiencies during battery operation.

To mitigate the issues, such as those illustrated in FIG. 3, BMS 110 described herein can employ a cell-level balancing system to equalize cell SOCs. While this may help facilitate the energy balancing, the rate at which balancing occurs can be limited by the module cell taps. The BMS 110 described herein can include module-level balancing, where energy can be transferred between modules 154. This can allow for faster balancing rates, given module terminals support higher current values.

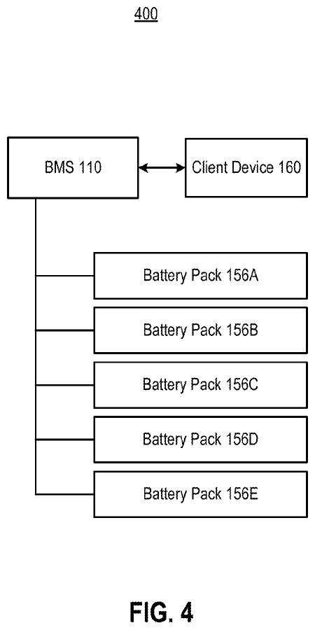

In addition to inferring SOC through the use of machine learning, the BMS 110 described herein can use the same available runtime data to infer SOH via trained ML models 112 by predicting cell capacities. For instance, an ML model 112 trained to determine SOH of a battery can be used for at least two purposes. For example, the ML model 112 (e.g., the SOH model) can track battery degradation in order to determine when an ESS (e.g., as in FIG. 4) or other BMS 110 component can benefit from maintenance or decommissioning in order to prevent poor performance caused by the use of end-of-life batteries. Additionally, SOH data can be used in load balancing applications such that batteries with high SOH have preference over those with low SOH to provide energy in order to equalize degradation across all batteries or ESSs 150 as in FIG. 4 (or other BMS components) within a deployment.

FIG. 4 illustrates an example of a battery management system (BMS) 110 for managing battery packs 156 of an ESS 150. The ESS 150 can include one or more circuit boards, such as battery circuits 158, for controlling operation of battery packs 156, including circuits for charging and discharging batteries. For instance, the BMS 110 can include the circuits or functionality for cell voltage measurement, temperature measurement, and cell balancing. The BMS 110 can include circuitry or functionality for providing safety or operational logic, non-safety functions such as data upload and pack LED control.

The BMS can include improvements, such as battery pack scalability features. The battery management systems and methods described herein can utilize batteries (e.g., 152, 154 or 156) from varying original equipment manufacturers (OEMs), such as for example, to diversify a supply chain. In an example, batteries can be homogeneous within one energy storage system (ESS). However, separate energy storage systems could contain different batteries, such as where all ESSs 150 within a deployment possessed a capacity greater than, for example 48 kWh. The underlying battery type can be transparent to the end application or customer. Given that OEM battery supply can differ with respect to both form factor and capacity, the number of managed cells used to provide 48 kWh of energy can depend on the cells in use. The systems and methods described herein can dynamically scale the number of cells under management in response to varying OEM battery characteristics. As a result, rather than being able to only support a limited number of cells, the technical solutions described herein can already use a maximum number of cells supported by a BMS (e.g., such as based on a BMS vendor design).

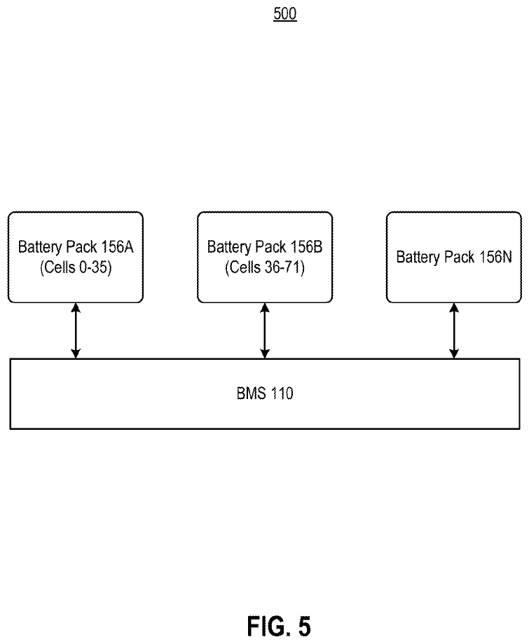

FIG. 5 illustrates an example 500 of a system having a battery management system 110 performing cell voltage measurements, temperature measurements and balancing control for battery cells 152. The BMS 110 can be configured to support, monitor, control and operate any number of cells, such as 2, 4, 12, 32, 64, 100, 400, 1000, 5000, or more than a 5000 cells. This approach can facilitate configurability with respect to cell type within the current ESS formfactor as well as the development of larger ESS 150 variants with higher capacities.

The technical solutions can provide flexibility and configurability with respect to the types of batteries used. For instance, due to a possible need to support many lithium-ion battery types, the BMS 110 described herein can include firmware that allows for a high degree of flexibility and configurability for various lithium-ion, or any other type, of batteries. Prior to managing a new battery, operating bounds relating to voltages, currents, and temperatures can be configured or reprogrammed to maintain proper operational tolerances.

The technical solutions can utilize ML functionalities. For instance, the BMS 110 described herein can reliably and accurately determine or infer the SOC of each cell in order to both ensure the proper operation of the pack, as well as enable the deployment of the energy management system to determine when the batteries should be charged or discharged. For instance, the BMS 110 described herein can rely on equivalent circuit models based on new lithium measurements to infer the SOC. However, as cells age their internal resistance can increase, leading to growing SOC inference errors over time for some implementations or techniques. For instance, lithium-ion cells can degrade at varying rates due to both manufacturing processes and environmental conditions. Due to the use of second-life batteries, large state of health (SOH) gradients can be expected both at the inter-module and intra-module scales. Because of these large SOH deltas, large SOC inference errors have been observed in some ML based techniques that utilize limited datasets.

For every ESS 150, such as the one in FIG. 4 that has been deployed, the ESS 150 or associated BMS 110 or data processing system 102 can collect and store all available runtime data. This data will can be used for numerous applications. For example, the collected deployment data can be used to both validate and aid in the training of the ML models 112. Given that ML models 112 for SOC, SOH, battery capacity or any other battery characteristic, can be trained using limited lab-collected data, long-term field data can increase both the accuracy and effectiveness of these tools. Further, using our generated SOC, SOH, or other data, the systems and methods described herein can identify capacity degradation trends associated with specific operating conditions. The systems and methods described herein can modify ESS runtime parameters such that these degradation periods can be avoided.

Example results of two separate BMS tests can show the versatility of the BMS described herein. The tests can involve the management of a grouping of cells, such that the voltage, temperature, current, balancing state, and other operating conditions are monitored over the course of a constant-current/constant-voltage (CCCV). The test sequence can be shown, for example, using a table below.

| Test | | |
|---|---|---|
| Step | Step Action | Step Exit Condition |
| 1 | Discharge cells | Cell group is at 0% SOC. |
| | at ~C/2 rate | |
| 2 | Discharge cells at | Discharge current falls below 5 A. |
| | a constant voltage. | |
| 3 | Charge cells at | Cell group is at 100% SOC. |
| | a ~C/2 rate. | |
| 4 | Charge cells at | Charge current falls below 5 A. |
| | a constant voltage. | |

The first test can include a group of 36 electric vehicle (EV) battery cells from a first OEM, whereas the second test can include a group of 12 battery cells from a second, different OEM. The BMS 110 described herein can be dynamically adjusted to both differing cell varieties and quantities, mimicking a deployment scenario involving the energy storage system (ESS) described herein that contains various cell types.

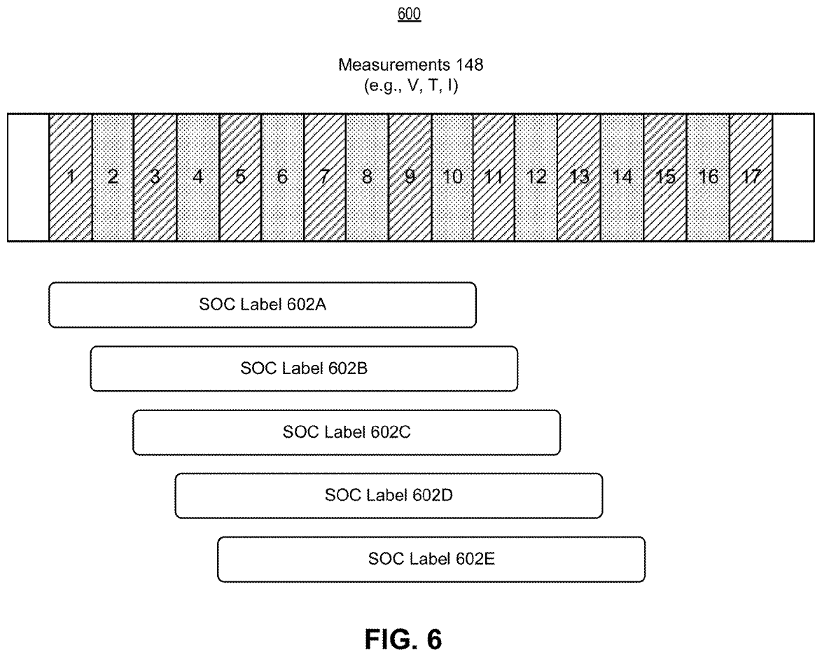

FIG. 6 illustrates an example 600 of SOC labels 602 corresponding to measurements 148 collected during testing. After capturing the test measurement data, ground truth SOC labels can be associated with groupings of data in order to train a machine learning (ML) model. To encode time-dependent behavior, such as lithium diffusion, measurements across a sliding window of a known length can be associated with a known SOC. SOC labels 602 can combine a plurality of measurements across a particular range, such as for example, 2, 8, 10, 15 or 20 consecutive measurements.

In example 600, an SOC label 602A can include an instantaneous SOC captured at the time of measurement 148 (e.g., measurements 1 through 17) and can include or correspond to data covering all of the prior 10 measurements (e.g., starting at measurement 1 and through measurement 10). Similarly, an SOC Label 602B can include an instantaneous SOC captured at the time of measurement 11 and can include data from the previous 10 measurements (e.g., starting at measurement 2). Likewise, SOC label 602C can cover measurements from 3 through 12, SOC label 602D can cover measurements from 4 through 13 and SOC label 602E can cover measurements from 5-14. SOC labeling implemented using the sliding window approach can last or continue until the end of all collected data (e.g., through measurement 17).

In order to obtain ground truth SOC labels, the battery-under-test can first be subjected to a rest period that is sufficiently long to facilitate all terminal voltages are open-circuit (OCV). For instance, prior to testing a battery cell, the battery cell can be rested (e.g., not used) for a period greater than four hours to ensure that all terminal voltages are open-circuit voltages (OCV). The OCVs from such a battery can be reliably mapped to a known starting SOC. Following a RW test, the cells can again be rested for greater than four hours, providing a known end SOC.

Since the net test current can be measured or known, total cell capacity can be calculated using the total SOC delta. Using the calculated cell capacity and the initial SOC, a coulomb-counting approach can be utilized in which the instantaneous net energy throughout the test is mapped to a SOC delta applied to the starting SOC. With each grouping of labeled time-series data a dataset can be compiled and fed into an ML training system. Once an ML model is trained, an SOC inference can take place on live measurement data grouped with the same structure as the dataset. For instance, data captured or measured during testing of batteries (e.g., cells, modules or packs) can be input into a trained ML model to provide an output of reliable SOC or SOH curves or datasets for each of the tested batteries.

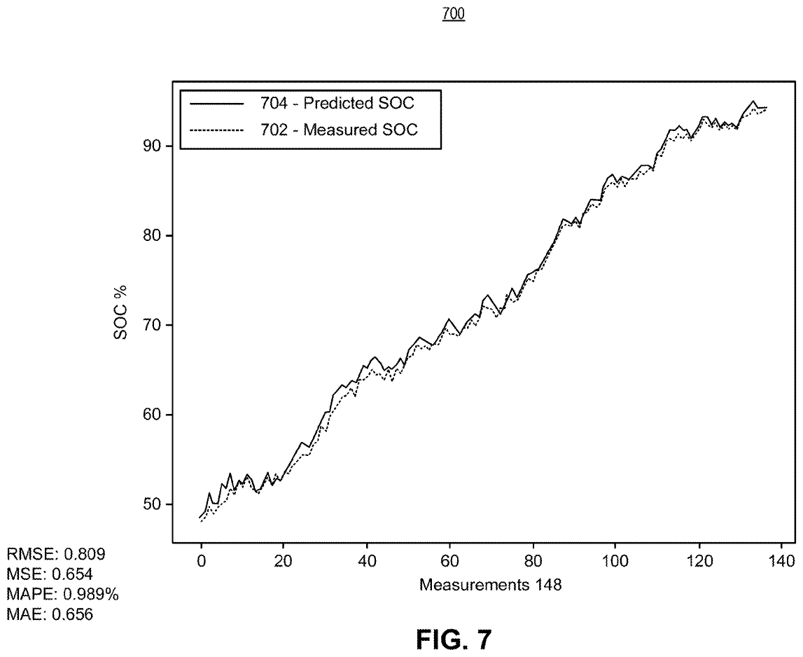

FIG. 7 illustrates an example graph 700 of a comparison of a plot 702 of measured SOC values and a plot 704 of ML model 112 outputs 114 (e.g., SOC determinations). Graph 700 can include measurements 148 as the x-axis and SOC percentages as the y-axis. Plots of a measured SOC 702 and predicted SOC 704 are illustrated closely aligning. For instance, in the illustrated example, ML model 112 predicts the SOC with accuracy such that the root mean square error (RMSE) between two plots is 0.809, mean squared error (MSE) is 0.654, mean absolute percentage error (MAPE) is 0.989%, and mean absolute error (MAE) is 0.656. These values collectively suggest that, on average, the differences between the predicted and actual SOC values are sub 1%, showcasing the effectiveness of the ML model in capturing and estimating battery state accurately.

In order to improve SOC inference accuracy over the lifetime of our product, the BMS systems and methods described herein can train ML models 112 to infer SOC based on available runtime data such as cell voltage, cell temperature, and pack current. As shown in graph 700, highly accurate inference results with SOC error rates under 1% across at least some operational bands.

System 100 can include one or more processors 210 coupled with memory (e.g., 215). The one or more processors 210 can implement or execute the functionalities of system 100 using computer code, instructions and data stored in the non-transitory computer readable media. The instructions, computer code or data can include the commands, parameters or data for implementing the functionalities of any portion of system 100, such as DPS 102. The one or more processors 210 can be centrally located (e.g., at a single device, such as a server) or can be distributed across one or more devices or platforms (e.g., cloud system).

System 100 can include the one or more processors configured to generate, according to a first constraint 122, a first random value (e.g., magnitude of current 126) for a first current 126 to charge a battery (e.g., 152, 154 or 156) for a first time duration (e.g., two or three minute period). The first current can be a charge current (e.g., power providing charge to the battery) or a discharge current (e.g., power taking charge from the battery). The first random value can correspond to amperage of current randomly selected between a range of currents defined by a pair of constraints corresponding to a minimum current and a maximum current. In some examples, the random value corresponds to a random time duration of the current to be applied. In some examples, the first random value can be selected within a range of a pair of constraints for current magnitudes (e.g., minimum and maximum current magnitudes) such that the value corresponds to a random value of amperage of the current, while another random value is selected according to a pair of constraints (e.g., minimum and maximum of time durations) to select the time duration for the current to be applied.

The one or more processors 210 can generate, according to a second constraint different than the first constraint, a second random value for a second current to discharge the battery for a second time duration. The second random value can correspond to a second amperage for a second current randomly selected within a range defined by one or more constraints (e.g., second constraints). For instance, if the first current corresponds to a charge current, the second current can correspond to a discharge current, and vice versa.

Sequence generator 118 can generate sequences of charge and discharge currents 126 to accomplish a random walk testing based on the parameters 116 provided from a client device 160. The parameters 116 can include source or starting SOC and a final or target SOC and battery capacity which the sequence generator 118 can use to establish the constraints 122 forming a range within which random values (e.g., current magnitudes) can be selected for the first and the second currents. Sequence generator 118 can generate or configure the constraints 122 so as to facilitate the random walk testing in a particular direction from the source SOC to the target SOC. Depending on the implementation, there can be multiple charge currents or multiple discharge currents. The charge and discharge currents can be sequenced such that they alternate with respect to each other. For instance, a discharge current 126 can be scheduled following a charge current 126 and prior to another charge current 126, so as to break up different charge currents 126 with an intervening discharge current 126, and vice versa.

The one or more processors 210 can measure a first voltage (e.g., measurement 148) corresponding to the first current and a second voltage (e.g., 148) corresponding to the second current. The first and the second voltage measurements 148 can be used to determine or measure SOC of the battery responsive to the random charge or discharge currents 126 applied to the battery. For instance, a battery tester 140 can include current, voltage and power sources or other power supply and power control circuitries (e.g., input circuitry 142) to apply currents 126 in the sequence arranged by the sequence generator 118. Output circuitry 144 of the battery tester 140 can include voltage or current meters or detectors, temperature detectors or coulomb counting devices or processing circuits for processing measured data. Output circuitry 144 can measure or establish measurements 148, such as the voltage measurements, current measurements, SOC measurements, responsive to the currents 126 input or applied to the batteries tested.

The one or more processors 210 can determine, based at least on the first current 126, the first voltage (e.g., voltage measurement 148 for the first current), the second current 126 and the second voltage (e.g., voltage measurement 148 for the second current) input into a machine learning (ML) model 112. The ML model 112 can be trained using at least a plurality of randomly selected currents 126 to charge a plurality of batteries and a plurality of randomly selected currents 126 to discharge the plurality of batteries, a state of charge (SOC) of the battery. The ML model 112 can be trained using a dataset 132 having measurements 148 (e.g., voltage outputs) measured responsive to the charge and discharge currents 126 applied to the plurality of batteries. ML model 112 can be trained using datasets of measurements 148 of the same type of batteries, such as the same make and model, same battery capacity or batteries within a range of battery capacities. ML model 112 can be trained on datasets for battery cells, battery modules or battery packs, according to the power, current, charge or voltage specifications (e.g., outputs and inputs) of such batteries.

ML model 112 The one or more processors 210 can operate the battery according to the SOC. For instance, the one or more processors 210 can implement or execute one or more battery operation functions (134) which can include functionalities facilitated by the BMS 110 utilizing outputs like SOC or SOC determinations (e.g., outputs 114). One or more processors 210 can implement energy management functions for batteries (e.g., 152, 154 or 156) such as establishment or control of charging and discharging cycles of the battery or regulating the extent of charging or discharging or adjusting or setting the overall battery performance, such as optimizing to maximize the battery operation, minimize or control heating or improve battery life. The one or more processors 210 operate the battery based on monitoring functions, integral to battery operation, involve tasks such as cycle counting, providing insights into the historical usage patterns of the battery. The one or more processors can implement load management functions to facilitate efficient utilization of the battery's capabilities, while preventative measures against overcharging or undercharging of individual battery cells 152 or battery modules 154, which can be utilized to improve the battery's health and extend its useful life. The one or more processors can set thresholds for charging and discharging the battery, thermal thresholds for operating the battery or any other battery management functionality based on determined SOC, SOH, battery capacity, and remaining useful life, or other characteristics determined using ML model 112.

The one or more processors 210 can identify a dataset 132 comprising a plurality of SOC outputs 114 (e.g., determinations) for a plurality of batteries. For instance, a dataset 132 can include measurements 148 of thousands of tested batteries, including batteries whose performance characteristics vary widely (e.g., varying SOC, SOH, battery capacity, battery age, battery make and model, battery efficiency or any other battery parameter). Each SOC of the plurality of SOCs can correspond to one or more timestamped measurements 148 of at least one of a voltage, a temperature or a current of a battery of the plurality of batteries. For instance, each measurement 148 can include a timestamp indicating the time (e.g., millisecond, second, minute, hour and date) of the measurement 148. Using the timestamps, the system 100 can order the measurements 148 into data structures to be stored as a portion of a dataset 132 in a database. Each of the plurality of timestamped measurements 148 can be measured using at least the plurality of randomly selected currents 126. The one or more processors 210 can train the ML model 112 using the dataset 132. For instance, as the ML model 112 is used for determining outputs 114 of additional batteries, these measurements 148 can be used to retrain and adjust the performance of the ML model 112.

The one or more processors 210 can select the first random value for the first current 126 from a first range of currents (e.g., random values) between the first constraint 122 and a third constraint 122. For example, the first constraint 122 can be 2 A and the third constraint 122 can be 0.8 A, whereas the first random value for the first magnitude of the current 126 can be selected as a random value between 1 and 2. For example, first constraint 122 can correspond to a first magnitude (e.g., 2.5 A of a current) that is greater than a third magnitude (e.g., 1.2 A of current) of the third constraint 122.

The one or more processors 210 can select the second random value for the second current from a second range of currents between the second constraint 122 and a fourth constraint 122. The second random value can correspond to a current 126 of the opposite polarity as the first current 126. For instance, if the first current 126 is a charging current, the second current 126 can be a discharging current. The second constraint 122 can correspond to a second magnitude that is greater than a fourth magnitude of the fourth constraint 122 and the fourth magnitude can be greater than at least one of the first magnitude or the third magnitude.

The one or more processors 210 can identify a temperature at which the first voltage and the second voltage (e.g., 148) are measured. The one or more processors 210 can determine, based at least on the temperature input into the ML model 112, the SOC of the battery. For instance, a specific value of the temperature can be input into the ML model 112 along with the first and second currents 126 and the first and second voltages (e.g., voltage measurements 148) measured responsive to the first and the second currents 126 applied to the tested battery at the measured valued of the temperature.

The one or more processors 210 can identify one or more parameters 116, including for example any one or more of: a starting SOC of the battery, a target SOC of the battery, a capacity of the battery, a coulombic efficiency of the battery and a target temperature for testing the battery. The one or more processors 210 can generate the first random value for the first current and the second random value for the second current according to the starting SOC, the target SOC, the capacity, the coulombic efficiency and the target temperature. For instance, the first randomly selected magnitude for the first current 126 can be selected based on a first set of constraints 122 forming a range of currents within which the first randomly selected magnitude of the first current 126 is to be selected. The first set of constraints 122 can be established based at least on any one or more parameters 116, including any combination of the starting SOC or target SOC, capacity, coulombic efficiency or target temperature.

The battery can include a plurality of battery cells 152, such as a battery module 154 or a battery pack 156. The starting SOC for testing such a plurality of battery cells 152 can correspond to a starting average or median SOC of the plurality of battery cells 152. The target SOC can correspond to a target average or a median SOC of the plurality of battery cells 152. The capacity can correspond to an average capacity of the plurality of battery cells 152. The coulombic efficiency can correspond to an average coulombic efficiency of the plurality of battery cells 152. The target temperature can correspond to an average temperature of the plurality of battery cells 152.

The one or more processors 210 can identify, based on a rule 124 for derating current, that the first random value for the first current 126 exceeds a threshold for a maximum current rating for the battery. The rule can be based on one or more variables or parameters, such as SOC, temperature and charge capacity. For instance, a rule 124 can set a limit to a maximum charge capacity of a battery or a maximum current rating. The one or more processors 210 can derate the first current 126 or the second current 126 according to the maximum current rating or the maximum charge capacity. The one or more processors 210 can derate the first current 126 or the second current 126 according to the temperature, SOC, charge capacity or any other parameter or variable indicative of a characteristic of the battery.

The one or more processors 210 can generate, according to the first constraint 122, a first plurality of random values for a first plurality of currents 126 to charge the battery. The first plurality of random values can include the first random value for the first current. Each of the first plurality of currents can have its magnitude (e.g., amperage) randomly selected according to a first one or more constraints (e.g., within a set range defined by the constraints 122).

The one or more processors 210 can generate, according to the second constraint 122, a second plurality of random values of currents 126 to discharge the battery. The second plurality of random values can have their magnitudes (e.g., amperages) randomly selected according to a second one or more constraints 122. The second plurality of random values comprising the second random value for the second current 126.

The one or more processors 210 can measure a first plurality of voltages (e.g., voltage measurements 148) corresponding to the first plurality of currents 126 and a second plurality of voltages (e.g., 148) corresponding to the second plurality of currents 126. The one or more processors 210 can determine the SOC of the battery, based at least on the first plurality of currents 126, the first plurality of voltages (e.g., 148), the second plurality of currents 126 and the second plurality of voltages (e.g., 148) input into the ML model 112. The one or more processors 210 can determine charging and discharging cycles for the battery based at least on the SOC. The one or more processors 210 can determine a state of health (SOH) of the battery using the charging and discharging cycles.

A Battery Management System (BMS) 110 can be used to infer or determine a SOC (e.g., output 114) of each battery cell 152 of a plurality of battery cells in a battery module 154 or a pack 156. These SOC determinations can be done continuously and in real-time. Timely determinations of the SOC can facilitate the safety of the battery pack and accurately inform the deployment's energy management system (EMS) of the current battery state such that it can make optimal usage decisions.

BMSs 110 can use any SOC inference or data collection or data measurement techniques, such as coulomb counting or equivalent circuit models. Coulomb counting can include summing the net measured current and subtracting the calculated energy from a known calibration SOC point (e.g., 100% SOC following a charge). However, coulomb counting can face various challenges. For example, due to the expected error involved in current sensor measurements, the calculated SOC can drift over time between the calibration points which can lead to errors in the SOC calculation as the known capacity of the battery can change due to degradation.

Equivalent circuit models can be used to determine or calculate a cell's open-circuit voltage (OCV) via cell terminal measurements. The determined OCV can be mapped to SOC using an OEM-provided lookup table. Equivalent circuit model parameters can be dependent on numerous factors including SOC, state-of-health (SOH), current, temperature and other unmeasurable internal parameters that are a product of side reactions during the lifetime of the battery. These factor affecting the results can involve complex analyses and determinations to provide accurate results. Depending on the battery's voltage characteristics, terminal voltage can be nearly constant between 30% and 70% SOC. Accordingly, precise voltage measurements are desired to differentiate SOCs within such a range.

To overcome challenges and facilitate reliable and accurate SOC determinations (e.g., outputs 114) over the lifetime of a battery pack, the technical solutions utilize trained machine learning (ML) models 112 to infer SOC based on, or using, runtime time-series voltage, temperature, and current data. To capture the effects of all external and internal runtime battery conditions, a data collection process can utilize sequences of random amounts or durations of charge or discharge currents to make SOC determinations. For instance, the technical solutions can utilize a random walk process in which random charge and discharge currents of alternating polarities cover the full SOC profile (e.g., by charging and discharging the battery across the SOC range). In doing so the technical solution can encode battery performance in terms of, or dependent on, any combination of: SOC, current, hysteresis, and time-dependent processes such as lithium diffusion within the collected dataset. By collecting such random walk data generated across a large range of modules at varying SOH levels, a model can be used to efficiently, accurately and reliably predict SOCs across the full lifetime of a battery.

The technical solutions can include a random walk sequence generator 118 for generating sequences of random charge and discharge currents 126. Random walk can include a process for determining a probable value or a probable location of a point on a graph using random motions, given the probabilities of moving some distance in some direction (e.g., up or down a SOC curve). The random walk sequence generator 118 can include a function, such as a script including instructions or commands, for generating the random currents used within an individual battery test. Such a sequence generating function (e.g., the sequencer 118) can be run for each tested battery (e.g., battery cell 152, module 154 or a pack 156), determining for each such tested battery its own test profile.

The random walk (RW) sequence generator 118 or sequencer can receive user input parameters 116, such as a starting SOC, a target end SOC, a battery capacity, a battery coulombic efficiency and target test temperature. Using these input parameters 116, the RW sequencer 118 can generate a sequence of random currents 126. The random currents 126 can have any combination of charging or discharging randomly selected current amounts (e.g., amperages) of current durations. Each of the random currents can be executed for a configurable amount of time such that the test concludes when the battery reaches the target end SOC. For example, tested profiles for the charge and discharge currents can use timestep lengths of between 0.5 and 5 minutes, such as 2 minutes.

When generating test step currents, the RW sequencer 118 can include a script or function that maintains a plurality of internal counters. These internal counters can include a major cycle step counter and the minor cycle step counter. The major cycle can be defined as a current in which the polarity aligns with the target charge/discharge direction, whereas a minor cycle can act against the target charge/discharge direction. For instance, if parameters 116 indicate that starting SOC is lower than target SOC, then the target charge/discharge direction is towards charging of the battery cell, and this direction can be established as the dominant, thereby biasing the constraints 122 accordingly to favor this direction. While the number of major cycle or minor cycle steps to be included can be configurable, the major cycle step value can be set up to be greater (e.g., have a range between greater values) than the minor cycle step value to facilitate that the battery covers the expected SOC range. For example, a test configurations can include 2 or 3 major cycles in a first direction (e.g., a charge direction or a discharge direction) followed by 1 minor cycle in a second direction that is opposite than the first direction.

Throughout the sequence generation process, the expected SOC can be approximated using the net effect of any combination (e.g., all) of the previous timesteps and the known battery capacity. The expected SOC value and the random current upper bounds can be determined (e.g., derated) according to one or more rules. For example, rules can be utilized for major cycles and minor cycles.

Major cycle rules can include a rule 124 that facilitates derating of the maximum random current to comply with the battery current ratings. For example, the originally calculated maximum current can be adjusted, according to a rule 124, downward to prevent exceeding the safe operating limits of the battery during a major cycle. Major cycle rules 124 can include a rule 124 that facilitates derating the maximum random current such that over voltage faults and under voltage faults do not occur through the timestep.

Minor cycle rules 124 can include a rule 124 that facilitates derating of the maximum random current to comply with the battery current ratings, such as to adjust the maximum calculated current to prevent exceeding the safe operating limits of the battery during a major cycle. Minor cycle rules 124 can include a rule 124 that facilitates derating the maximum random current such that over voltage faults and under voltage faults do not occur through the timestep. Minor cycle rules 124 can include a rule 124 that limits the maximum random current to the theoretical maximum major cycle current if this value is less than the previous limitations. This can facilitate the test completion at SOC extremes where the maximum major current can be smaller than the maximum minor current. By limiting the minor cycle current to the theoretical maximum major cycle current, the test can progress smoothly through different SOC levels.

The current profiles for multiple temperatures can be included in the RW sequencer script. In such implementations, the max random current can be influenced by the test target temperature parameter, which can be provided or configured by the user. Once started, the RW sequencer script (e.g., 118 or 120) can continue to add the configured number of major cycle steps, followed by the configured number of minor cycle steps. This process of adding cycles can continue until a random current during a major cycle step results in the battery crossing the target end SOC threshold. The RW sequencer script (e.g., 118 or 120) and the associated model 112 can vary based on the specific battery type, such that each battery type (e.g., make or model) can have its own individual datasets, based on which outputs can be generated.

Depending on the implementation, the RW test can be executed at any battery level or configuration, including battery cell 152, module 154, or pack level 156 or configuration. However, when testing is done for battery modules or battery packs, RW sequencer script configuration parameters 116, such as starting SOC, target end SOC and capacity, can be interpreted as average values of the battery cells or modules of cells, depending on the configuration.

Once a RW sequence is generated, a test profile can be loaded into a user's cycler profile of the test setup to test the battery. When the test execution is complete, measurements 148, such as the cell voltage, temperature, and current measurements made during the test can be captured and logged. In some implementations, multiple, such as two, RW testing portions can be completed. A first RW test can include testing from a low SOC to a high SOC (e.g., a random walk towards a high SOC), while the second RW test can include testing from a high SOC to a low SOC (e.g., a random walk towards a low SOC). For example, a test of a battery can collect approximately an equal amounts of charge and discharge data.

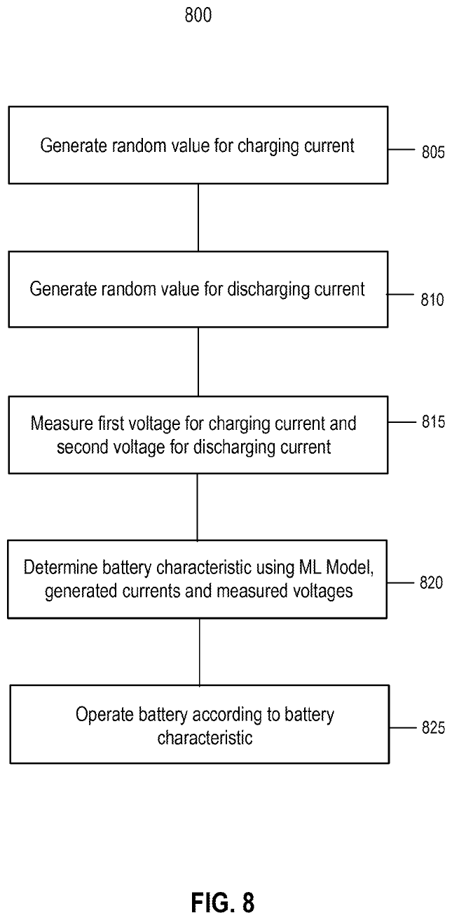

FIG. 8 illustrates a method 800 for determining battery characteristics (e.g., SOC or SOH) using ML models trained with datasets generated with measurements gathered via random walk battery testing applying random charge and discharge current to batteries under test. The method 800 can be performed by one or more systems or components depicted in FIGS. 1-13, including, for example, a data processing system having a battery cooling model implemented on one or more processors of a computer system 200 of system 100 implemented on one or more computing systems 200. In brief overview, the method 800 can include ACTS 805-825. At ACT 805, the method generate a random value for a charging current. At ACT 810, the method can generate a random value for a discharging current. At ACT 815, the method can measure a first voltage for a charging current and a second voltage for a discharging current. At ACT 820, the method can determine a battery characteristic using an ML model, the generated currents and the measured voltages. At ACT 825, the method can operate a battery according to the determined battery characteristics.

At ACT 805, the method generate a random value for a charging current. The method can include one or more processors coupled with memory generating, according to a first constraint, a first random value for a first current to charge a battery for a first time duration. The one or more processors can generate a first random value for a magnitude (e.g., amperage value) for a first current (e.g., a charging current) for charging a battery (e.g., a battery cell, a battery module or a battery pack). The first value can be generated from a range defined by a pair of constraints, such as a first and a second constraint defining maximum and minimum value of the range from which to randomly generate a value for the charging current.

The method can include the one or more processors generating, according to the first constraint, a first plurality of random values for a first plurality of currents to charge the battery, the first plurality of random values comprising the first random value for the first current. For example, a plurality of random values can be generated for a plurality of currents (e.g., charging or discharging currents). The currents can be generated for a random walk sequence of charging and discharging currents.

The method can include the one or more processors identifying one or more parameters, which can be provided by a user via a client device. The one or more parameters can include: a starting SOC of the battery, a target SOC of the battery, a capacity of the battery, a coulombic efficiency of the battery and a target temperature for testing the battery. The one or more processors can generate the first random value for the first current and the second random value for the second current according to the starting SOC, the target SOC, the capacity, the coulombic efficiency and the target temperature. For example, the one or more processors can utilize the sequence generator to generate, configure or set up a first pair of constraints for randomly generated charging currents and a second pair of constraints for randomly generated discharging currents. The first and the second pair of constraints can bias or tilt the charging or discharging currents to be more dominant or have greater amperage, thereby allowing for random walk technique to be implemented towards an increased SOC or decreased SOC of the tested battery.

The method can include one or more currents having their time durations randomly selected from a pair of constraints. For example, charge durations can be randomly selected from a range of constraints, so as to allow an amount of charge or discharge to be dominant for the purpose of the battery testing. The battery can include a battery cell being tested or a plurality of battery cells being tested. When testing a plurality of battery cells (e.g., a battery module or a pack), the starting SOC can correspond to a starting average or a median value of SOC of the plurality of battery cells. The target SOC can correspond to a target average or a median SOC of the plurality of battery cells. The capacity can correspond to an average or a median capacity of the plurality of battery cells. The coulombic efficiency can correspond to an average or a median coulombic efficiency of the plurality of battery cells. The target temperature can correspond to an average or a median temperature of the plurality of battery cells.

The method can include the one or more processors selecting the first random value for the first current that can be selected from a first range of currents between the first constraint and a third constraint. The first constraint can correspond to a first magnitude that is greater than a third magnitude of the third constraint. The method can include the one or more processors identifying a dataset comprising a plurality of SOCs for a plurality of batteries. Each SOC of the plurality of SOCs can correspond to one or more timestamped measurements of at least one of a voltage, a temperature or a current of a battery of the plurality of batteries. Each of the plurality of timestamped measurements measured can use at least the plurality of randomly selected currents. The one or more processors can implement a model trainer to train the ML model using the dataset that can include a plurality of measurements, such as voltages measured responsive to various charge and discharge current sequences implemented in a random walk pattern.

At ACT 810, the method can generate a random value for a discharging current. The method can include the one or more processors generating, according to a second constraint different than the first constraint, a second random value for a second current to discharge the battery for a second time duration. The first current and the second current can be of the opposite polarity, such that the first current is for example a charging current, and the second current is a discharging current and vice versa. The generating of the second random value for the second current can utilize any techniques, such as those discussed at ACT 805.

The one or more processors can generate, according to the second constraint, a second plurality of random values of currents to discharge the battery. The second plurality of random values can include the second random value for the second current. The second plurality of random values can correspond to random magnitudes of the second current polarity. The one or more processors can select the second random value for the second current from a second range of currents between the second constraint and a fourth constraint. The second constraint can correspond to a second magnitude that is greater than a fourth magnitude of the fourth constraint. The fourth magnitude of the fourth constraint for the second current can be greater than at least one of the first magnitude or the third magnitude corresponding to the magnitudes for the constraints for the first current. As such, the second current can be selected from a range of current amplitudes that is biased to have an expected value for the magnitude for the second current to be greater than the expected value for the magnitude of the first current.

At ACT 815, the method can measure a first voltage for a charging current and a second voltage for a discharging current. The method can include the one or more processors measuring a first voltage corresponding to the first current and a second voltage corresponding to the second current. For example, a battery tester can apply the sequency of one or more first currents and the one or more second currents and measure the one or more voltages resulting from the currents applied to the battery being tested.

The method can include the one or more processors measuring a first plurality of voltages corresponding to the first plurality of currents and a second plurality of voltages corresponding to the second plurality of currents. The method can include the one or more processors identifying, based on a rule for derating current, that the first random value for the first current exceeds a threshold for a maximum current rating for the battery, a maximum temperature of the battery or a maximum capacity of the battery. The method can include the one or more processors derating the first current according to the maximum current rating, the maximum temperature of the battery or the maximum capacity of the battery.

At ACT 820, the method can determine a battery characteristic using an ML model, the generated currents and the measured voltages. The method can include the one or more processors determining a characteristic of the battery, such as a SOC, SOH, battery capacity or a remaining useful life of the battery. The ML model can determine the characteristic of the battery, based at least on the first current, the first voltage, the second current and the second voltage input into a machine learning (ML) model. The ML model can be trained using at least a dataset generated using a plurality of randomly selected currents to charge a plurality of batteries and a plurality of randomly selected currents to discharge the plurality of batteries. The ML model can be trained using a dataset of a plurality of measurements made based on the random walk currents applied to the battery, such as the first and the second voltage measurements.

The method can include the one or more processors determining, based at least on the first plurality of currents, the first plurality of voltages, the second plurality of currents and the second plurality of voltages input into the ML model, the SOC of the battery. The method can include the one or more processors identifying a temperature at which the first voltage and the second voltage are measured. The method can include the one or more processors determining, based at least on the temperature input into the ML model, the SOC of the battery.

At ACT 825, the method can operate a battery according to the determined battery characteristics. The method can include the one or more processors operating the battery according to the SOC. The one or more processors can implement or execute one or more battery operation functions which can include functionalities facilitated by the BMS using outputs such as SOC or SOC determinations. One or more processors can implement energy management functions for batteries (e.g., battery cells, modules or packs) including establishment or control of charging and discharging cycles of the battery or regulating the extent of charging or discharging. Operating battery can include adjusting or setting the overall battery performance, such as optimizing to maximize the battery operation, minimize or control heating or improve battery life. The one or more processors can operate the battery based on monitoring functions, integral to battery operation and involve tasks such as cycle counting, providing insights into the historical usage patterns of the battery. The one or more processors can implement load management functions to facilitate efficient utilization of the battery's capabilities. The one or more processors can operate the battery according to set thresholds for charging and discharging the battery, thermal thresholds for operating the battery or any other battery management functionality based on determined SOC, SOH, battery capacity, and remaining useful life, or other characteristics determined using ML model.

As displayed above, the BMS described herein is operational, and includes numerous technological improvements in comparison to other BMSs. With the ability to manage both varying cell quantities and cell types, the developed BMS described herein provides technical advantages.

The processes, systems and methods described herein can be implemented by the computing system in response to the processor executing an arrangement of instructions contained in main memory. Such instructions can be read into main memory from another computer-readable medium, such as the storage device. Execution of the arrangement of instructions contained in main memory causes the computing system to perform the illustrative processes described herein. One or more processors in a multi-processing arrangement may also be employed to execute the instructions contained in main memory. Hard-wired circuitry can be used in place of or in combination with software instructions together with the systems and methods described herein. Systems and methods described herein are not limited to any specific combination of hardware circuitry and software.

The subject matter including the operations described in this specification can be implemented in other types of digital electronic circuitry, or in computer software, firmware, or hardware, including the structures disclosed in this specification and their structural equivalents, or in combinations of one or more of them.

Some of the description herein emphasizes the structural independence of the aspects of the system components or groupings of operations and responsibilities of these system components. Other groupings that execute similar overall operations are within the scope of the present application. Modules can be implemented in hardware or as computer instructions on a non-transient computer readable storage medium, and modules can be distributed across various hardware or computer based components.

The systems described above can provide multiple ones of any or each of those components and these components can be provided on either a standalone system or on multiple instantiation in a distributed system. In addition, the systems and methods described herein can be provided as one or more computer-readable programs or executable instructions embodied on or in one or more articles of manufacture. The article of manufacture can be cloud storage, a hard disk, a CD-ROM, a flash memory card, a PROM, a RAM, a ROM, or a magnetic tape. The computer-readable programs can be implemented in any programming language, such as LISP, PERL, C, C++, C#, PROLOG, or in any byte code language such as JAVA. The software programs or executable instructions can be stored on or in one or more articles of manufacture as object code.

The subject matter and the operations described in this specification can be implemented in digital electronic circuitry, or in computer software, firmware, or hardware, including the structures disclosed in this specification and their structural equivalents, or in combinations of one or more of them. The subject matter described in this specification can be implemented as one or more computer programs, e.g., one or more circuits of computer program instructions, encoded on one or more computer storage media for execution by, or to control the operation of, data processing apparatuses. Alternatively, or in addition, the program instructions can be encoded on an artificially generated propagated signal, e.g., a machine-generated electrical, optical, or electromagnetic signal that is generated to encode information for transmission to suitable receiver apparatus for execution by a data processing apparatus. A computer storage medium can be, or be included in, a computer-readable storage device, a computer-readable storage substrate, a random or serial access memory array or device, or a combination of one or more of them. While a computer storage medium is not a propagated signal, a computer storage medium can be a source or destination of computer program instructions encoded in an artificially generated propagated signal. The computer storage medium can also be, or be included in, one or more separate components or media (e.g., multiple CDs, disks, or other storage devices include cloud storage). The operations described in this specification can be implemented as operations performed by a data processing apparatus on data stored on one or more computer-readable storage devices or received from other sources.

The terms “computing device”, “component” or “data processing apparatus” or the like encompass various apparatuses, devices, and machines for processing data, including by way of example a programmable processor, a computer, a system on a chip, or multiple ones, or combinations of the foregoing. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (e.g., a program, software, software application, app, script, or code) can be written in any form of programming language, including compiled or interpreted languages, declarative or procedural languages, and can be deployed in any form, including as a stand-alone program or as a module, component, subroutine, object, or other unit suitable for use in a computing environment. A computer program can correspond to a file in a file system. A computer program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform actions by operating on input data and generating output. The processes and logic flows can also be performed by, and apparatuses can also be implemented as, special purpose logic circuitry, e.g., an FPGA (field programmable gate array) or an ASIC (application specific integrated circuit).

Devices suitable for storing computer program instructions and data can include non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The subject matter described herein can be implemented in a computing system that includes a back end component, e.g., as a data server, or that includes a middleware component, e.g., an application server, or that includes a front end component, e.g., a client computer having a graphical user interface or a web browser through which a user can interact with an implementation of the subject matter described in this specification, or a combination of one or more such back end, middleware, or front end components. The components of the system can be interconnected by any form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

While operations are depicted in the drawings in a particular order, such operations are not required to be performed in the particular order shown or in sequential order, and all illustrated operations are not required to be performed. Actions described herein can be performed in a different order.

Having now described some illustrative implementations, it is apparent that the foregoing is illustrative and not limiting, having been presented by way of example. In particular, although many of the examples presented herein involve specific combinations of method acts or system elements, those acts, and those elements may be combined in other ways to accomplish the same objectives. Acts, elements and features discussed in connection with one implementation are not intended to be excluded from a similar role in other implementations or implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation or embodiment, and references to “an implementation,” “some implementations,” “one implementation” or the like are not necessarily mutually exclusive and are intended to indicate that a particular feature, structure, or characteristic described in connection with the implementation may be included in at least one implementation or embodiment. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Such references used in conjunction with “comprising” or other open terminology can include additional items.

Where technical features in the drawings, detailed description or any claim are followed by reference signs, the reference signs have been included to increase the intelligibility of the drawings, detailed description, and claims. Accordingly, neither the reference signs nor their absence have any limiting effect on the scope of any claim elements.

Modifications of described elements and acts such as variations in sizes, dimensions, structures, shapes and proportions of the various elements, values of parameters, mounting arrangements, use of materials, colors, orientations can occur without materially departing from the teachings and advantages of the subject matter disclosed herein. For example, elements shown as integrally formed can be constructed of multiple parts or elements, the position of elements can be reversed or otherwise varied, and the nature or number of discrete elements or positions can be altered or varied. Other substitutions, modifications, changes and omissions can also be made in the design, operating conditions and arrangement of the disclosed elements and operations without departing from the scope of the present disclosure.

Further relative parallel, perpendicular, vertical or other positioning or orientation descriptions include variations within +/−10% or +/−10 degrees of pure vertical, parallel or perpendicular positioning. References to “approximately,” “substantially” or other terms of degree include variations of +/−10% from the given measurement, unit, or range unless explicitly indicated otherwise. Coupled elements can be electrically, mechanically, or physically coupled with one another directly or with intervening elements. Scope of the systems and methods described herein is thus indicated by the appended claims, rather than the foregoing description, and changes that come within the meaning and range of equivalency of the claims are embraced therein.

What is claimed is:

1. A system, comprising:
one or more processors coupled with memory to:
generate, according to a first constraint, a first random value for a first current to charge a battery for a first time duration;
generate, according to a second constraint different than the first constraint, a second random value for a second current to discharge the battery for a second time duration;
measure a first voltage corresponding to the first current and a second voltage corresponding to the second current;
determine, based at least on the first current, the first voltage, the second current and the second voltage input into a machine learning (ML) model trained using at least a plurality of randomly generated currents to charge a plurality of batteries and a plurality of randomly generated currents to discharge the plurality of batteries, a state of charge (SOC) of the battery; and
operate the battery according to the SOC.

2. The system of claim 1, comprising the one or more processors to:
identify a dataset comprising a plurality of SOCs for a plurality of batteries, each SOC of the plurality of SOCs corresponding to one or more timestamped measurements of at least one of a voltage, a temperature or a current of a battery of the plurality of batteries, each of the plurality of timestamped measurements measured using at least the plurality of randomly selected currents; and
train the ML model using the dataset.

3. The system of claim 1, comprising the one or more processors to:
select the first random value for the first current from a first range of currents between the first constraint and a third constraint, wherein the first constraint corresponds to a first magnitude that is greater than a third magnitude of the third constraint.

4. The system of claim 3, comprising the one or more processors to:
select the second random value for the second current from a second range of currents between the second constraint and a fourth constraint, wherein the second constraint corresponds to a second magnitude that is greater than a fourth magnitude of the fourth constraint and the fourth magnitude is greater than at least one of the first magnitude or the third magnitude.

5. The system of claim 1, comprising the one or more processors to:
identify a temperature at which the first voltage and the second voltage are measured; and
determine, based at least on the temperature input into the ML model, the SOC of the battery.

6. The system of claim 1, comprising the one or more processors to:
identify a starting SOC of the battery, a target SOC of the battery, a capacity of the battery, a coulombic efficiency of the battery and a target temperature for testing the battery; and
generate the first random value for the first current and the second random value for the second current according to the starting SOC, the target SOC, the capacity, the coulombic efficiency and the target temperature.

7. The system of claim 6, wherein the battery comprises a plurality of battery cells and the starting SOC corresponds to a starting average SOC of the plurality of battery cells, the target SOC corresponds to a target average SOC of the plurality of battery cells, the capacity corresponds to an average capacity of the plurality of battery cells, the coulombic efficiency corresponds to an average coulombic efficiency of the plurality of battery cells and the target temperature corresponds to an average temperature of the plurality of battery cells.

8. The system of claim 1, comprising the one or more processors to:
identify, based on a rule for derating current, that the first random value for the first current exceeds a threshold for a maximum current rating for the battery; and
derate the first current according to the maximum current rating.

9. The system of claim 1, comprising the one or more processors to:
generate, according to the first constraint, a first plurality of random values for a first plurality of currents to charge the battery, the first plurality of random values comprising the first random value for the first current;
generate, according to the second constraint, a second plurality of random values of currents to discharge the battery, the second plurality of random values comprising the second random value for the second current;
measure a first plurality of voltages corresponding to the first plurality of currents and a second plurality of voltages corresponding to the second plurality of currents; and
determine, based at least on the first plurality of currents, the first plurality of voltages, the second plurality of currents and the second plurality of voltages input into the ML model, the SOC of the battery.

10. The system of claim 1, comprising the one or more processors to:
determine charging and discharging cycles for the battery based at least on the SOC; and
determine a state of health (SOH) of the battery using the charging and discharging cycles.

11. A method, comprising:
generating, by one or more processors coupled with memory, according to a first constraint, a first random value for a first current to charge a battery for a first time duration;
generating, by the one or more processors, according to a second constraint different than the first constraint, a second random value for a second current to discharge the battery for a second time duration;
measuring, by the one or more processors, a first voltage corresponding to the first current and a second voltage corresponding to the second current;
determining, by the one or more processors, based at least on the first current, the first voltage, the second current and the second voltage input into a machine learning (ML) model trained using at least a plurality of randomly generated currents to charge a plurality of batteries and a plurality of randomly generated currents to discharge the plurality of batteries, a state of charge (SOC) of the battery; and
operating, by the one or more processors, the battery according to the SOC.

12. The method of claim 11, comprising:
identifying, by the one or more processors, a dataset comprising a plurality of SOCs for a plurality of batteries, each SOC of the plurality of SOCs corresponding to one or more timestamped measurements of at least one of a voltage, a temperature or a current of a battery of the plurality of batteries, each of the plurality of timestamped measurements measured using at least the plurality of randomly selected currents;
training, by the one or more processors, the ML model using the dataset.

13. The method of claim 11, comprising:
selecting, by the one or more processors, the first random value for the first current is selected from a first range of currents between the first constraint and a third constraint, wherein the first constraint corresponds to a first magnitude that is greater than a third magnitude of the third constraint.

14. The method of claim 13, comprising:
selecting, by the one or more processors, the second random value for the second current from a second range of currents between the second constraint and a fourth constraint, wherein the second constraint corresponds to a second magnitude that is greater than a fourth magnitude of the fourth constraint and the fourth magnitude is greater than at least one of the first magnitude or the third magnitude.

15. The method of claim 11, comprising:
identifying, by the one or more processors, a temperature at which the first voltage and the second voltage are measured; and
determining, by the one or more processors, based at least on the temperature input into the ML model, the SOC of the battery.

16. The method of claim 11, comprising:
identifying, by the one or more processors, a starting SOC of the battery, a target SOC of the battery, a capacity of the battery, a coulombic efficiency of the battery and a target temperature for testing the battery; and
generating, by the one or more processors, the first random value for the first current and the second random value for the second current according to the starting SOC, the target SOC, the capacity, the coulombic efficiency and the target temperature.

17. The method of claim 16, wherein the battery comprises a plurality of battery cells and the starting SOC corresponds to a starting average SOC of the plurality of battery cells, the target SOC corresponds to a target average SOC of the plurality of battery cells, the capacity corresponds to an average capacity of the plurality of battery cells, the coulombic efficiency corresponds to an average coulombic efficiency of the plurality of battery cells and the target temperature corresponds to an average temperature of the plurality of battery cells.

18. The method of claim 11, comprising:
identifying, by the one or more processors, based on a rule for derating current, that the first random value for the first current exceeds a threshold for a maximum current rating for the battery; and
derating, by the one or more processors, the first current according to the maximum current rating.

19. The method of claim 11, comprising:
generating, by the one or more processors, according to the first constraint, a first plurality of random values for a first plurality of currents to charge the battery, the first plurality of random values comprising the first random value for the first current;
generating, by the one or more processors, according to the second constraint, a second plurality of random values of currents to discharge the battery, the second plurality of random values comprising the second random value for the second current;
measuring, by the one or more processors, a first plurality of voltages corresponding to the first plurality of currents and a second plurality of voltages corresponding to the second plurality of currents; and
determining, by the one or more processors, based at least on the first plurality of currents, the first plurality of voltages, the second plurality of currents and the second plurality of voltages input into the ML model, the SOC of the battery.

20. A non-transitory computer readable media having processor readable instructions, such that, when executed, cause at least one processor to:
generate, according to a first constraint, a first random value for a first current to charge a battery for a first time duration;
generate, according to a second constraint different than the first constraint, a second random value for a second current to discharge the battery for a second time duration;
measure a first voltage corresponding to the first current and a second voltage corresponding to the second current;
determine, based at least on the first current, the first voltage, the second current and the second voltage input into a machine learning (ML) model trained using at least a plurality of randomly generated currents to charge a plurality of batteries and a plurality of randomly generated currents to discharge the plurality of batteries, one of a state of charge (SOC) of the battery or a state of health (SOH) of the battery; and
operate the battery according to the SOC or the SOH.
